(19) United States
(12) Patent Application Publication
(10) Pub. No.: US 2005/0274865 A1
(43) Pub. Date: Dec. 15, 2005

(54) Combination rack assembly and monitor support

(76) Inventors: William N. Touzani, (US); Malika Belhaj, (US)

Correspondence Address: N/A, N/A, Alexandria, VA, 22313-1450, US

(21) Appl. No.: 10/864,168

(22) Filed: Jun. 10, 2004

(51) Int. Cl. A47G 29/00; H05K 5/00; G06F 1/16

(52) U.S. Cl. 248/346.01

(57) ABSTRACT

In one embodiment, a rack assembly for storing digital media comprising a plurality of parallel U-shaped channels comprising substantially vertical side walls for supporting the weight of a computer monitor or alike, and whereas the spacing between the vertical side walls of each channel is adapted for receiving CD or DVD cases. The rack assembly may include a slidable platform for supporting a monitor, and support means for holding the rack assembly above the desktop surface for inserting a computer keyboard. In another embodiment, the rack assembly includes a slidable keyboard tray mounted along the supporting lateral side walls for moving the keyboard tray between a work position and a storage position located directly under the rack assembly.

### FIELD OF THE INVENTION

The present disclosure relates, in general, to a media storage system and method and, more particularly, to such a system and method for supporting a computer monitor and digital media.

### BACKGROUND OF THE INVENTION

With the huge popularity of recordable media such as recordable CDs and DVDs, the dramatic price decreases for R/W players and software, consumers are now making their own private libraries and collections of selected music and movies and other entertainments. Whether the work involves copying, down loading from the internet or developing original work, the time spent in front of a computer is very substantial (as in the making of a multimedia presentation on CD) and may require using source material from a multitude of CDs and DVDS.

While there're many means for organizing and storing CDs, including shelves, racks or binders, there's little that has been created to reduce the problem of clutter on a desktop during an ongoing work session.

A work in progress is generally monitored on the computer screen, as material from a variety of CDs and DVDs is been imputed. The same CDs may be used several times requiring the user to keep them on the desktop for immediate accessibility. As CDs and empty cases pile up on the surface of a desktop using-up valuable space, they also become prone to damage and abuse.

Desktop keyboard drawers can reduce some desktop clutter by providing additional space beneath the monitor for storing a computer keyboard.

Computer monitor and keyboard supports are well known in the prior. Typical examples are shown in U.S. Pat. Nos. 4,483,572; 4,496,200; 4,624,510; 4,635,893; 4,717,112; and 4,901,972.

Other desktop organizers are described in U.S. Pat. No. 5,265,735, while a monitor support device with a rotary apparatus for holding CDs and alike is described in U.S. Pat. No. 6,588,609.

While many inventions deal with long term storage of digital media, none of the prior art resolves the problem of a temporary storage of compact disks and their empty cases during a work session in progress.

While desktop keyboard drawers help in reducing some of the clutter, the outer cabinet is generally made of a metal chassis for supporting the excessive weight of a monitor. Plastic constructions have being mostly unpractical.

Therefore, what is needed is a more practical storage system and a method for storing, organizing and accessing entertainment and/or computer media for a work in progress in the immediate vicinity of a computer monitor. Furthermore, the plastic construction of a keyboard drawer cabinet is now possible according to the present invention, because of the unique monitor support platform design.

### SUMMERY OF THE INVENTION

To this end, according to one embodiment of the invention, a combination of a monitor stand and CD rack to temporarily store CDs or DVDs with or without their cases is provided. While the CD rack assembly is made of a plurality of U-shaped channels or CD tracks to receive CD cases, the computer monitor is preferably resting on a tray or platform which is adapted to support a computer monitor or alike. The monitor, with or without the platform, can be moved left or right along the longitudinal axis of the CD tracks, depending on the operators preference.

Construction of the rack assembly as described in the invention would provide a large number of U-shaped ribs with twice as many vertical walls, that would make the use of a plastic injected monitor stand possible.

It is an object of the present invention to provide a support for a computer monitor that can include a slidable platform or base for supporting a monitor or alike, a CD rack assembly consisting of a plurality of U-shaped channels for storing CDs, DVD cases and alike, and legs or side walls, for holding the rack assembly above the desktop and providing sufficient storage room directly underneath it for storing a keyboard.

By moving the slidable monitor platform to one side, additional room for storing additional CD cases is exposed along the U-shaped channels at the opposite side of the platform.

In another object of the invention, the rack assembly and side walls can also include a slidable tray adapted to support a keyboard, with means for transporting the keyboard tray between a forward work position and a backward storage position.

Other features and advantages of the present invention are stated in or apparent from a detailed description of a presently preferred embodiment of the invention found hereinbelow.

### BRIEF DESCRIPTION OF THE DRAWINGS

FIG. 1 is a perspective partial view of a portion of a monitor support and rack assembly.

FIG. 2 is a cross section view taken near the middle of the monitor support and rack assembly as shown in FIG. 1 with a compact disk placed in the middle and legs normally located at the extremities of the rack assembly.

FIG. 3 is a perspective magnified view of one leg and its corresponding slot within the rack assembly.

FIG. 4 is a perspective view of a desktop drawer including a computer monitor support and rack assembly with a slidable keyboard tray.

### DETAILED DESCRIPTION OF THE INVENTION

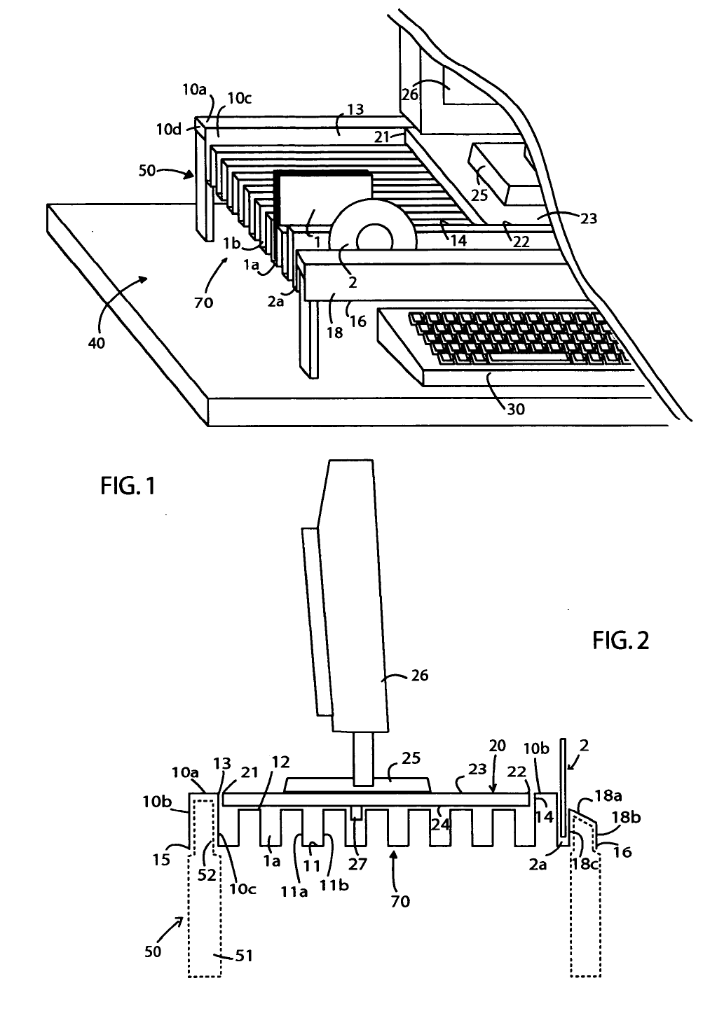

With reference to FIGS. 1, 2 and 3 in which a preferred form of this invention has been illustrated, it should be noted that the monitor support assembly consists of a slidable platform indicated generally at 20, a CD rack assembly 70 consisting of a plurality of U-shaped channels 1a and 2a for storing CDs, DVD cases and alike, and legs 50, for providing sufficient storage room directly underneath the CD rack for storing keyboard 30.

The various elements from the monitor support assembly of the invention can be constructed from plastics, wood or metal or a combination thereof.

Monitor platform 20 includes a generally planar top surface 23 which is adapted to support a computer monitor or alike, while opposed surface 24 is adapted to be slidable against upper surfaces 12 of the rack assembly 70, with respect to the CD rack assembly 70 and the desktop 40.

FIGS. 1 and 2 show monitor platform 20 restrained by sections 13 and 14 in allowing transversal motions. Other conventional mechanisms may also be incorporated to the sliding platform 20, such as a tongue and groove combination, slides or rails along the sections generally indicated by monitor base extremities 21 and 22 and corresponding sections 13 and 14, or simply protrusions or runners 27 for guiding platform assembly 20 along any of the existing U-shaped channels represented by 1a and 2a.

FIG. 2 also shows a cross section of the monitor support and rack assembly 70 of the invention including monitor screen 25 and base 26, a plurality of parallel U-shaped channels 1a adapted to hold CDs or DVD cases 1, channel 2a for holding CDs 2 without cases, slot 10 with its respective wall portions 10a, 10b, 10c and 10d, and slot 18 with its respective wall portions 18a, 18b, 18c and 18d for receiving legs 50. Legs 50 shown in dotted line (because it is normally located at the far side of the rack assembly) may also be an integral part of the rack assembly 70. For practical or esthetic purposes, the extremities 15 and 16 of rack assembly 70 may be extended downwardly further than the base of the U-shaped channels 11.

By moving the slidable platform to one side, additional room is exposed along the U-shaped channels 1a or 2a, that may allow the storage of additional CD cases 1 or 2, while an equal amount of space is lost at the opposite side of the slidable platform 20.

The rack assembly 70 and platform assembly 20 of the invention may be placed on any computer shelf or desktop as a free standing unit

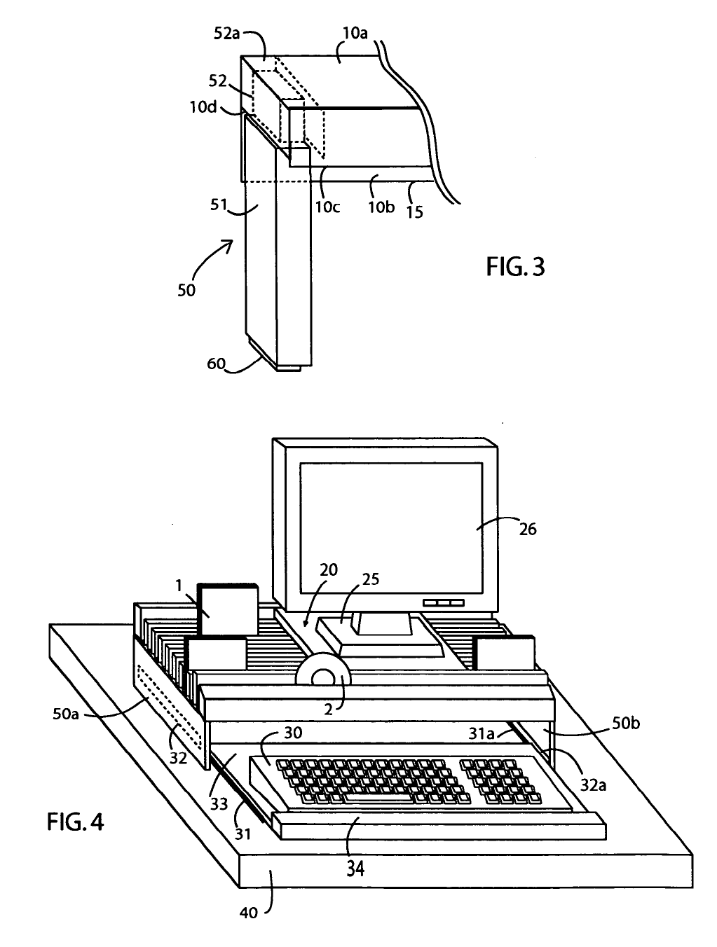

FIG. 3 shows a magnified view of legs 50 including a narrow top section 52 adapted to engage inside slot 10 in a tight fit provided by inner side walls 10a, 10b and 10c, and downwardly extended sections 51. Legs 51 and their extremities 52 can include a variety of shapes and interconnecting mechanisms.

Member 60 represents a rubber pad or alike for preventing damage to the desktop surface.

FIG. 4 shows a support device for a computer monitor 26 comprising a slidable platform or base 20 for supporting a monitor or alike, a CD rack assembly 70 consisting of a plurality of U-shaped channels for storing CDs, DVD cases 1 and alike, two side walls 50a and 50b for elevating and holding the rack assembly several inches above the desktop 40, and providing sufficient storage room directly underneath it for receiving a slidable keyboard support tray 33, wrist support 34 and any of a variety of available means for supporting and sliding the keyboard tray 33 such as a tongue and groove combination, nested slides or rails along the sections generally indicated by keyboard tray extremities 31 and 31a and corresponding side wall sections 32 and 32a.

1. A support device for a computer monitor or alike comprising,
a CD rack assembly consisting of a plurality of parallel U-shaped channels for storing CDs, DVD cases and alike, and
lateral support means for holding the rack assembly above the desktop surface adapted to provide sufficient storage room for a computer keyboard.

2. A support device according to claim 1, wherein said support device further includes a platform or base for holding said computer monitor.

3. A support device according to claim 2, wherein said platform is slidable left or right with respect to said rack assembly.

4. A support device according to claim 1, wherein said lateral support means include a plurality of attachable legs.

5. A support device according to claim 1, wherein said lateral support means are an integral part of said rack assembly.

6. A support device according to claim 1, wherein said lateral support means include at least two side walls.

7. A support device according to claim 1, wherein said lateral support means include a slidable tray adapted to support a keyboard, with means for transporting said tray between a forward work position and a backward storage position

8. A rack assembly for storing digital media comprising a plurality of parallel U-shaped channels and a planar monitor platform, wherein said channel, comprising a pair of substantially vertical side walls for supporting the weight of a computer monitor or alike, and wherein the spacing between said vertical side walls is of sufficient width for receiving at least a single CD or DVD case.

9. A rack assembly of claim 8 including a slidable platform for supporting said monitor.

10. A rack assembly of claim 8 including lateral support means adapted for holding said assembly above the desktop surface for receiving a keyboard.

11. A rack assembly of claim 10 including a slidable keyboard tray mounted to lateral support walls for moving said keyboard tray between a work position and a storage position.
